(19) United States
(12) Patent Application Publication
(10) Pub. No.: US 2008/0278912 A1
(43) Pub. Date: Nov. 13, 2008

(54) THERMAL MANAGEMENT SYSTEMS AND METHODS FOR ELECTRONIC COMPONENTS IN A SEALED ENCLOSURE

(76) Inventors: Dean Zavadsky, Shakopee, MN (US); Michael J. Wayman, Waconia, MN (US)

Correspondence Address: FOGG & POWERS LLC, 10 SOUTH FIFTH STREET, SUITE 1000, MINNEAPOLIS, MN, 55402, US

(21) Appl. No.: 11/746,199

(22) Filed: May 9, 2007

(51) Int. Cl. H05K 7/20

(52) U.S. Cl. 361/697; 361/694; 361/695

(57) ABSTRACT

Systems and methods for thermal management for electronic components in a sealed enclosure are provided. In one embodiment, a thermal management system for electronic components in a sealed enclosure comprises: an enclosure for housing electronic components, the enclosure sealed from an external environment; a card cage housed within the enclosure; at least one electronic device card installed in the card cage; and at least one baffle configured to form an airflow channel through at least part of the card cage, wherein the airflow channel directs air warmed by thermal energy from the at least one electronic device card to follow a circular path along an internal surface of the enclosure, wherein the internal surface is configured to conductively remove heat from the air to the environment external to the enclosure.

### BACKGROUND

Increasingly, additional service demands are placed on telecommunications system networks. These additional service demands involve operating at optimal speeds to accommodate voice and data traffic on the networks. Accommodating these traffic demands translates into additional thermal energy created by electronic components in the system. The electronic components are contained in chassis throughout the system. Preferably, these chassis are sealed in an enclosure from the surrounding exterior environment. The enclosure protects the electronic components from any environmental contaminants (for example, rain, dust, and debris) entering the enclosure.

Since the volume within the enclosure is finite, the components are strategically placed in various locations throughout the enclosure. These strategic locations complicate access to the components and, in most instances, contribute to excessive thermal energy that accumulates within the enclosure over time. A loss of any critical components in the chassis due to inadequate cooling has significant economic and reliability implications for telecommunications network operators.

For the reasons stated above and for other reasons stated below which will become apparent to those skilled in the art upon reading and understanding the present specification, there is a need in the art for improvements in managing thermal energy from a plurality of electronic components in a sealed enclosure while providing accessibility to these components.

### SUMMARY

The following specification discusses a thermal management system for electronic components in a sealed enclosure. This summary is made by way of example and not by way of limitation. It is merely provided to aid the reader in understanding some aspects of at least one embodiment described in the following specification.

Particularly, in one embodiment, a thermal management system for electronic components in an enclosure sealed from an external environment is provided. The system comprises: an enclosure for housing electronic components, the enclosure sealed from an external environment; a card cage housed within the enclosure; at least one electronic device card installed in the card cage; and at least one baffle configured to form an airflow channel through at least part of the card cage, wherein the airflow channel directs air warmed by thermal energy from the at least one electronic device card to follow a circular path along an internal surface of the enclosure, wherein the internal surface is configured to conductively remove heat from the air to the environment external to the enclosure.

### DRAWINGS

These and other features, aspects, and advantages are better understood with regard to the following description, appended claims, and accompanying drawings where:

FIG. 1 is a block diagram of a thermal management system for a sealed enclosure of one embodiment of the present invention;

FIG. 2 is a cross-sectional view of the device of a thermal management system for a sealed enclosure of one embodiment of the present invention;

FIG. 3 is a cross-sectional view of a cooling component for a thermal management system for a sealed enclosure of one embodiment of the present invention;

FIG. 4 is an exploded perspective view of a thermal management system for a sealed enclosure of one embodiment of the present invention;

FIG. 5 is a flow diagram of a method for managing thermal energy in a sealed enclosure of one embodiment of the present invention; and

FIG. 6 is a flow diagram of a method for producing a thermal management system for a sealed enclosure of one embodiment of the present invention.

The various described features are drawn to emphasize features relevant to the embodiments disclosed. Reference characters denote like elements throughout the figures and text of the specification.

### DETAILED DESCRIPTION

The following detailed description describes at least one embodiment of a thermal management system for electronic components in a sealed enclosure. In the embodiment described, the sealed enclosure houses electronic device cards and other electronics for operating in a telecommunications network system. Other embodiments for sealed enclosures housing other types of electronics, however, are also contemplated as within the scope of embodiments of the present invention.

Advantageously, thermal energy generated from the electronic components on the device cards is transported away from an internal card cage housing the device cards by either one or both of convective and forced circulation of air sealed within the enclosure. The thermal management systems provided by embodiments of the present invention ensure the device cards continue to function as designed within their rated temperature ranges. Further, access to the device cards for maintenance and repair is improved as device cards installed in the card cage are removably coupled to a backplane. The backplane provides easy access to the device cards and simplifies circuit card configurations within the card cage because the device cards are no longer rigidly connected to the enclosure. In one embodiment, electronic devices other than those installed in the internal card cage are also mounted directly to the inner surface of the enclosure. These devices typically dissipate sufficiently high power levels necessitating direct mounting to the inner surface to allow for conductive cooling.

Within the sealed enclosure and flowing through the card cage is at least one air channel (formed by heat sink fins and/or other internal structures as described below) that directs the air within the sealed enclosure to flow along a circular path. In one embodiment, the air is directed to flow through heat sink fins along the internal surface of the sealed enclosure, which service to facilitate the removal of thermal energy (for example, heat) from the air. Opposing heat sink fins on the external surface of the sealed enclosure, in turn, facilitate removal of that thermal energy to the external environment surrounding the sealed enclosure. In alternate embodiments, air sealed within the enclosure may circulate along the air channel through natural convection, or through forced circulation.

The thermal management system for the sealed enclosure discussed here has several distinct advantages. First, the card cage design allows easy access to the device cards, as explained above. Second, the chassis backplane eliminates additional connector cables for interfacing the device cards. Third, the enclosure remains sealed with respect to the outside environment. Fourth, the height of the enclosure (and the length of the circular air path), along with the heat sink fin dimensions, are scaled for a prescribed amount of heat dissipation based on a predetermined power output of the electronic components. Fifth, high powered electronics can be mounted directly to the inside of the enclosure wall, while non-heat generating components can be housed in the center of the sealed enclosure out of the cooling airflow pattern.

For purposes of this description, the term “major electronics” identifies any high-power electronic components in the sealed enclosure that generate a substantial amount of thermal energy and are placed within the forced air flow discussed above. The term “minor electronics” identifies those electronic components that generate substantially less thermal energy as compared to the major electronics. In one embodiment, one or more minor electronics device maintain operation by dissipating any thermal energy they produce through indirect cooling within the sealed enclosure (for example, by conduction through the at least one enclosure panel). In one embodiment, a sealed enclosure includes sub-compartments that include only minor electronics. Such a sub-compartment is referred to herein as a “minor electronics compartment.”

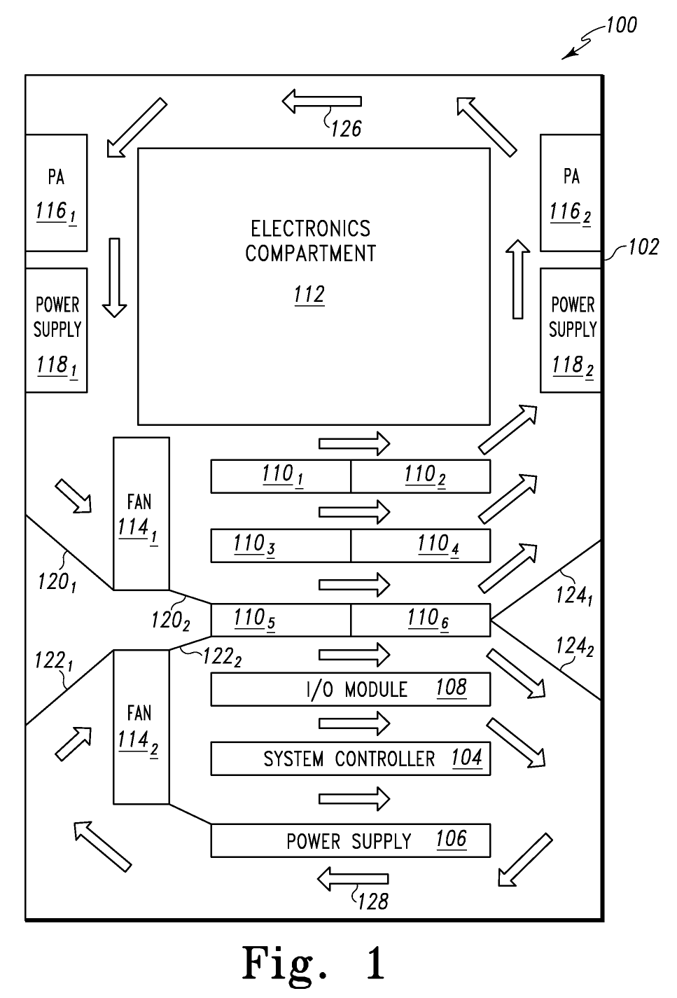

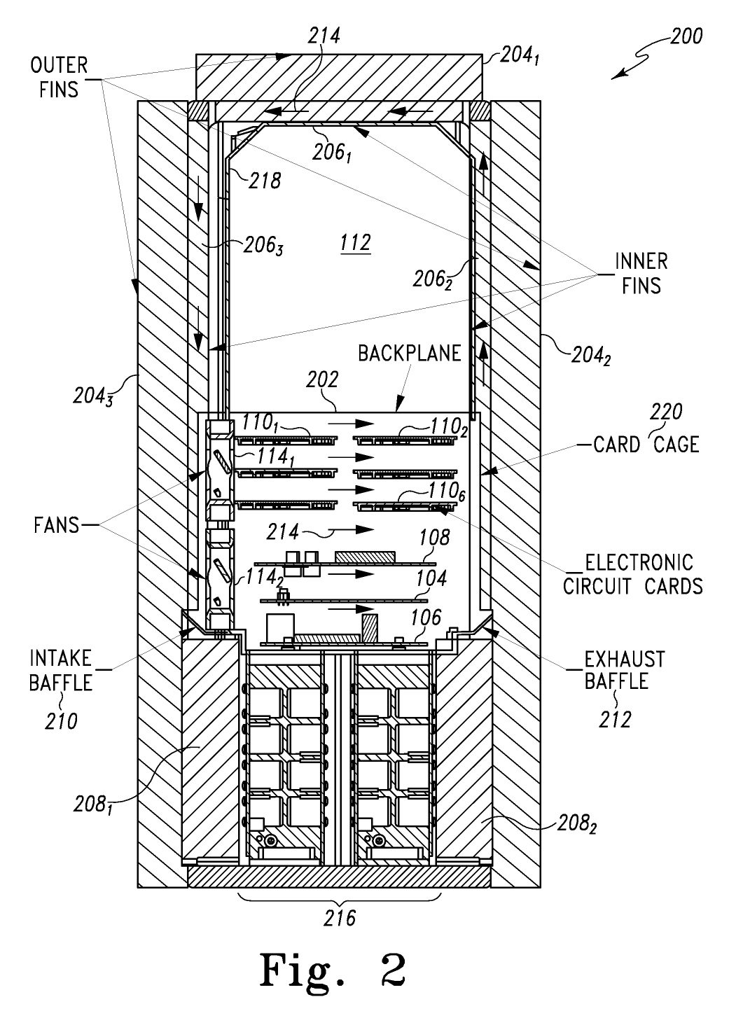

FIG. 1 is a block diagram of an electronics device 100. In the example embodiment of FIG. 1, the device 100 represents a sealed remote communications enclosure 102 in a telecommunication network system. The sealed enclosure 102 comprises electronic device cards including, for example, but not limited to, a system controller 104, a power supply 106, an input/output (I/O) module 108, and transceiver modules 110₁ to 110₆. These electronic device cards are installed in a card cage structure discussed below with respect to FIG. 2. The sealed enclosure 102 further comprises a minor electronics compartment 112, and power amplifiers 116₁ and 116₂, and system power supplies 118₁ to 118₂ mounted directly to the internal surface of enclosure 102. In the embodiment of FIG. 1, the power amplifiers 116₁ to 116₂ are major components that are mounted at a separate location from the electronic device cards to facilitate direct conduction through the structure of enclosure 102 into the external environment. In one embodiment, each of the power amplifiers 116₁ to 116₂ is a linear power amplifier (LPA) coupled to the system power supplies 118₁ to 118₂, respectively. It is understood that in alternate embodiments, the device 100 is capable of accommodating any appropriate number of the I/O modules 108, the transceiver modules 110, the power amplifiers 116, and the system power supplies 118, along with other electronic modules.

The sealed enclosure 102 further includes at least one set of intake baffles (for example, first intake baffles 120₁ and 120₂ and second intake baffles 122₁ and 122₂) and exhaust baffles (for example, exhaust baffles 124₁ and 124₂). It is understood that the sealed enclosure 102 is capable of accommodating any appropriate number of the intake baffles 120 and 122 and the exhaust baffles 124 required to directed air along the designed paths of the air flow channels. In particular, the sealed enclosure 102 shown in FIG. 1 forms at least two airflow channels 126 and 128. As shown in FIG. 1, airflow channel 126 directs air flow along a path that substantially surrounds a minor electronics compartment 112.

In operation, the power supply 106 supplies electrical power to the electronic device cards installed in the card cage structure and to optional fan assemblies 114₁ and 114₂. In one implementation, the optional fan assemblies 114₁ and 114₂ are responsive to the system controller 104. The I/O module 108 sends and receives communication data (for example, communication data amplified by the power amplifiers 116₁ and 116₂) between at least one external communication device (not shown) and the device 100 for further processing by each of the transceiver modules 111 to 110₆. In one implementation, a prescribed temperature threshold is monitored by the system controller 104. Moreover, in one implementation, optional fan assemblies 114 are variable-speed fans 114₁ and 114₂. In one such implementation, fan assemblies 114₁ and 114₂ vary their fan speeds depending on the temperature level that the system controller 104 observes. In at least one alternate embodiment, the fan assemblies 114₁ and 114₂ operate continuously to ensure that the temperature threshold does not exceed a prescribed electronic component temperature operating range of the electronic device cards.

In the example embodiment of FIG. 1, the thermal energy distribution provided by the airflow channels 126 and 128 maintain the temperature level inside the sealed enclosure 102 below the prescribed temperature threshold level. The intake baffles 120₁ and 120₂ direct a first airflow pattern created by the airflow channel 126 through the fan 114₁ and orients a first airflow for the airflow channel 126 through a first portion of the electronic device cards in the sealed enclosure 102 (for example, the transceiver modules 110₁ to 110₆) in the first airflow direction depicted in FIG. 1. The exhaust baffle 124₁ directs the air warmed by thermal energy from the transceiver modules 110₁ to 1106 and the power amplifiers 116 and the power amplifier power supplies 118 to follow a first circular path of the airflow channel 126. Similarly, the intake baffles 122₁ and 122₂ direct a second airflow pattern created by the airflow channel 128 through the fan 114₂ and orients a second airflow for the airflow channel 128 through at least a second portion of the electronic device cards in the sealed enclosure 102 (for example, the transceiver modules 1105 and 1106, the I/O module 108, the system controller 104, and the power supply 106) in the second airflow direction depicted in FIG. 1. The exhaust baffle 1242 directs the air warmed by thermal energy from the second portion of the electronic device card to follow a second circular path of the airflow channel 128.

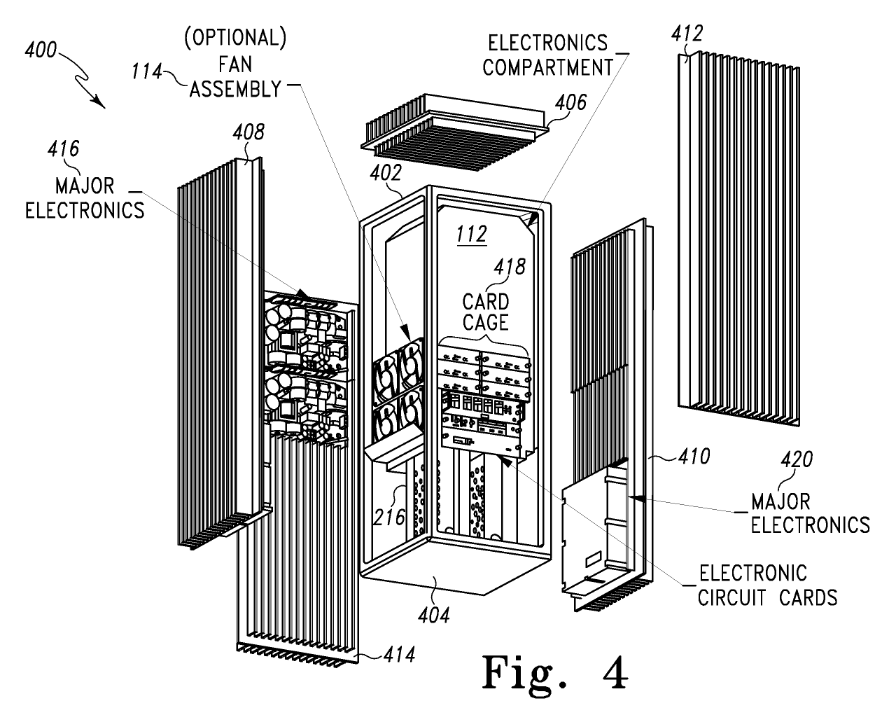

As noted above, FIG. 1 illustrates one embodiment of an airflow diagram for the device 100. It is to be understood that other embodiments are implemented in other ways. Indeed, the device 100 illustrated in FIG. 1 is adaptable for a wide variety of applications. For example, FIG. 2 is a cross-sectional view of a sealed enclosure 200 with an alternate airflow diagram. The sealed enclosure 200 further comprises outer heat sink fins 204₁ to 204₃, inner heat sink fins 206₁ to 206₃, and a compartment cooling surface 218 substantially surrounding the passive electronics compartment 112. The outer heat sink fins 204 and the inner heat sink fins 206 form at least one conductive extrusion panel as described in further detail below with respect to FIG. 4. In the example embodiment of FIG. 2, opposing inner heat sink fins 208₁ and 208₂ conductively cool the system component module 216. The sealed enclosure 200 further includes the optional variable-speed fans 114₁ and 114₂ positioned at an intake end to convectively channel the thermal energy away from the plurality of electronic device cards (for example, the system controller 104, the power supply 106, the I/O module 108, and the transceiver modules 110₁ to 110₆) as indicated in FIG. 2. The plurality of electronic device cards are operatively connected to, and (in one implementation) supported by, a backplane 202. In this same implementation, the plurality of electronic device cards is installed in an internal card cage 220. The sealed enclosure 200 further comprises an intake baffle 210 adjacent to a first side of the internal card cage 220 and an exhaust baffle 212 adjacent to a second side of the internal card cage 220, with the intake baffle 210 opposing the exhaust baffle 212 as shown in FIG. 2. The intake baffle 210 and the exhaust baffle 212 are configured to form at least one airflow pattern with an airflow channel 214 as depicted in FIG. 2.

In operation, the airflow channel 214 forces the air to flow along a circular path that directs air warmed by thermal energy from the electronic device cards to the inner heat sink fins 206 and the outer heat sink fins 204. In one implementation, the fan assemblies 114 force the air to convectively follow the circular path comprising the airflow channel 214. Moreover, each of the inner heat sink fins 206₁ to 206₃ conduct the thermal energy in the circular path across the compartment cooling surface 218 to the outer heat sink fins 204₁ to 204₃ and into an environment external to the enclosure 200.

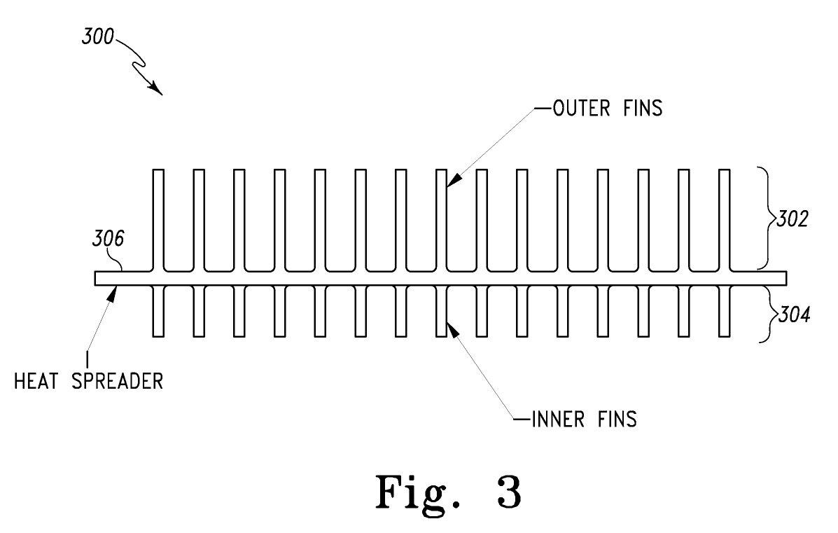

FIG. 3 is a cross-sectional view of an enclosure panel heat sink 300 comprising the outer heat sink fins 204₁ to 204₃ and inner heat sink fins 206₁ to 206₃ of FIG. 2. In the example embodiment of FIG. 3, the enclosure panel heat sink 300 comprises a set of inner heat sink fins 304 opposing a set of outer heat sink fins 302 separated by a heat spreader 306. The heat spreader 306 dissipates the thermal energy absorbed by the inner heat sink fins 304 on any of the conductive extrusion panels illustrated below with respect to FIG. 4 through the outer heat sink fins 302. In one implementation, a first outer length of the heat sink fins 302 and a first inner length of the heat sink fins 304 is determined from a power output of the plurality of electronic circuits cards (for example, the system controller 104, the power supply 106, the I/O module 108, and the transceiver modules 110) and other major electronic components (for example, the power amplifiers 116). Depending of the amount of thermal energy generated within a sealed enclosure, the length of the heat sink fins 302 and 304 can be accordingly designed (for example, the inner heat sink fins are designed to be longer as relatively more thermal energy must be dissipated within the space available in the sealed enclosure).

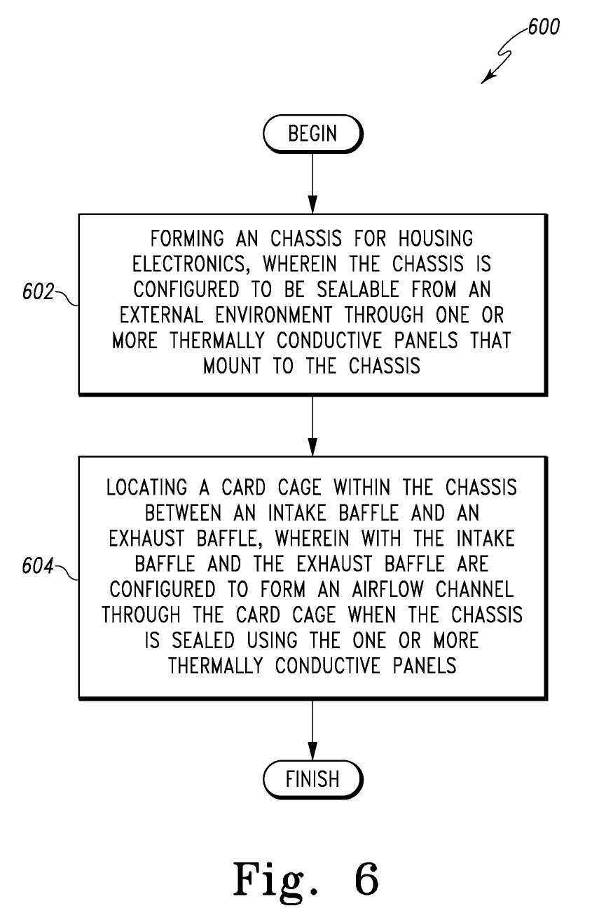

FIG. 4 is an exploded perspective view of a sealed enclosure 400. In one embodiment, sealed enclosure 400 depicts sealed enclosure 100 as shown with respect to FIG. 1. The enclosure 400 comprises an enclosure structure 402 (also referred to herein as a chassis) having a base 404. In the example embodiment of FIG. 4, the enclosure structure 402 houses an internal card cage 418 that contains the system controller 104, the power supply 106, the input/output module 108, and the transceiver modules 110₁ to 110₆, along with the optional fan assemblies 114 of FIG. 1. The enclosure structure 402 further includes at least one system component module 216 and the minor electronics compartment 112 of FIG. 1. Surrounding the enclosure structure 402 are conductive extrusion panels 406, 408, 410, 412 and 414 configured to attach to at least one rim surface of the enclosure structure 402, respectively. Attachment of the conductive extrusion panels 406, 408, 410, 412, and 414 with screws, clamps latches or other mechanical devices combined with a perimeter seal effectively seal the enclosure structure 402 from an external environment to form the environmentally-sealed enclosure 400 (discussed in further detail below with respect to FIG. 6). In the example embodiment of FIG. 4, the conductive extrusion panel 414 includes a plurality of active electronics embodied by a first major electronics subassembly 416. In the same embodiment, the conductive extrusion panel 410 includes a second major electronics subassembly 420.

The sealed enclosure 400 forms the airflow channels described above with respect to FIGS. 1 and 2 when each of the conductive extrusion panels 406, 408, 410, 412 and 414 are attached to the enclosure structure 402. The airflow channels of the sealed enclosure 400 substantially surround the minor electronics compartment 112 and distribute thermal energy from the plurality of electronic device cards in the internal card cage 418 to surface areas on any of the conductive extrusion panels 406, 408, 410, 412 and 414. In one implementation, the thermal energy distribution provided by the airflow channels maintains a temperature level inside the sealed enclosure 400 below a prescribed temperature threshold level.

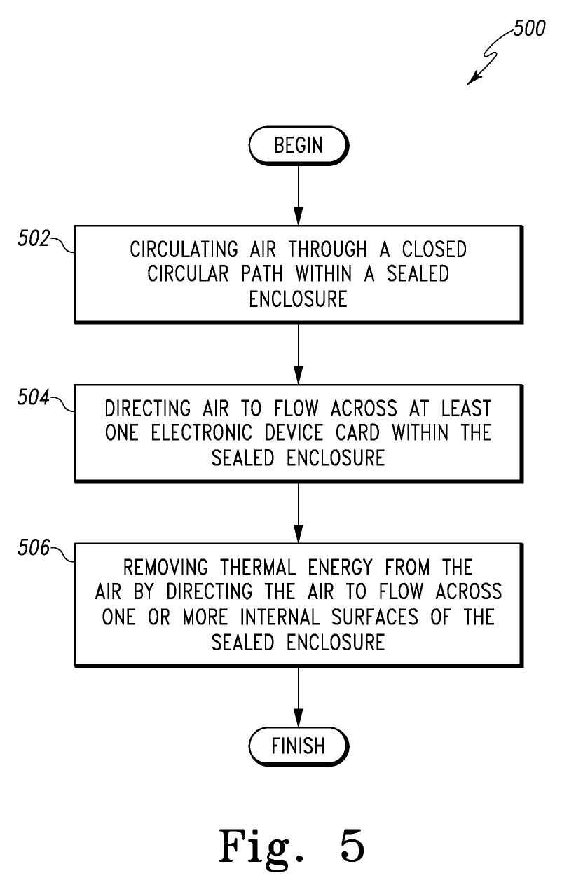

FIG. 5 is a flow diagram illustrating a method 500 for managing thermal energy in a sealed enclosure such as, but not limited to, the sealed enclosures shown with respect to FIGS. 1, 2 and 4. The method begins at 502 with circulating air through a closed circular path within a sealed enclosure. In one embodiment, air is circulated through the natural circulation process generated through convection. That is, air within the sealed enclosure that is heated by electronic devices is rises up along the closed circular path, cooling as it reaches the highest point in the path. The cooled air then falls back to the electronic devices to complete the closed circular path. In another embodiment, circulating air comprises forcing the air through the closed circular path using a cooling assembly, such as but not limited to a fan. The method proceeds to 504 with directing air to flow across at least one electronic device card within the sealed enclosure. Because of the circulation provided in 502, the air directed across the electronic device card will be relatively cooled, allowing the air to absorb thermal energy radiation from the electronic device card. In one embodiment, when the sealed enclosure is sealed enclosure 102, the electronic device card can include any of the system controller 104, the power supply 106, the I/O module 108, and the transceiver modules 110₁ to 110₆, installed within a card cage. In one embodiment, air flow is directed through the card cage. In one embodiment, the air flow is directed in 504 using one or more sets of baffles and/or heat sink fins. The method proceeds to 506 with removing thermal energy from the air by directing the air to flow across one or more internal surface of the sealed enclosure. In one embodiment, the one or more internal surfaces of the sealed enclosure include heat sink fins that absorb thermal energy from the air and transfer the thermal energy to an environment external to the sealed enclosure. In one embodiment, the internal surfaces comprise the conductive extrusion panels 406, 408, 410, 412 and 414 shown with respect to FIG. 4.

FIG. 6 is a flow diagram illustrating a method 600 for producing a thermal management system for a sealed enclosure such as, but not limited to, the sealed enclosures shown with respect to FIGS. 1, 2 and 4. The method begins at 602 with forming a chassis for housing electronics, wherein the chassis is configured to be sealable from an external environment through one or more thermally conductive panels that mount to the chassis. In one embodiment, the chassis comprises an enclosure structure such as enclosure structure 402 shown with respect to FIG. 4 and the one or more thermally conductive panels comprise the conductive extrusion panels 406, 408, 410, 412 and 414 that are attachable to the enclosure structure 402. The method proceeds to 604 with locating a card cage within the chassis between an intake baffle and an exhaust baffle, wherein with the intake baffle and the exhaust baffle are configured to form an airflow channel through the card cage when the chassis is sealed using the one or more thermally conductive panels. In one embodiment, the airflow channel directs an airflow over and under one or more electronic device cards in the card cage, wherein each of the electronic device cards is oriented parallel to the direction of the airflow.

In one implementation, the method of FIG. 6 ensures access to each of the electronic device cards from at least one side of the enclosure. Once the enclosure is sealed, at least one airflow channel circulates air from the plurality of electronic device cards to the extrusion panels and allows the extrusion panels to dissipate thermal energy from the circulated air into an external environment substantially surrounding the sealed enclosure and maintain the temperature level inside the assembly below the prescribed temperature threshold level. In one implementation, an optional fan assembly (for example, the optional fan assembly 114) is directed at the plurality of electronic device cards to force the directed airflow to the extrusion surface areas. The method of FIG. 6 further comprises forming the thermally conductive panels with at least one set of heat sinks, the at least one set of heat sinks further formed with opposing inner and outer fins to create at least one airflow pattern. In addition, the internal card cage supports a least a portion of the electronic device cards connected to a chassis backplane assembly (for example, the backplane 202 of FIG. 2).

This description has been presented for purposes of illustration, and is not intended to be exhaustive or limited to the embodiment(s) disclosed. The disclosed embodiments are intended to cover any modifications, adaptations, or variations which fall within the scope of the following claims.

What is claimed is:

1. A thermal management system for electronic components in a sealed enclosure, the system comprising:
an enclosure for housing electronic components, the enclosure sealed from an external environment;
a card cage housed within the enclosure;
at least one electronic device card installed in the card cage; and
at least one baffle configured to form an airflow channel through at least part of the card cage, wherein the airflow channel directs air warmed by thermal energy from the at least one electronic device card to follow a circular path along an internal surface of the enclosure, wherein the internal surface is configured to conductively remove heat from the air to the environment external to the enclosure.

2. The system of claim 1, further comprising:
a plurality of panels configured to attach to the enclosure and seal the enclosure from the external environment.

3. The system of claim 2, wherein each of the plurality of panels comprises at least one set of heat sinks with opposing inner fins and outer fins separated by a heat spreader to dissipate the thermal energy absorbed by the inner fins through the outer fins.

4. The system of claim 3, wherein inner fin lengths and outer fin lengths are scaled based on one or both of a power output of the plurality of electronic components and space available for the inner fins.

5. The system of claim 1, further comprising a fan assembly that forces the air to follow the circular path of the airflow channel.

6. The system of claim 1, wherein the internal surface of the enclosure comprises heat sink fins.

7. The system of claim 1, wherein the airflow channel is configured to allow the air to convectively follow the circular path of the airflow channel.

8. The system of claim 1, further comprising:
an electronics compartment, wherein the airflow channel is configured to direct air across the electronics compartment.

9. The system of claim 8, wherein the airflow channel substantially surrounds the electronics compartment.

10. The system of claim 1, further comprising:
at least one electronic device mounted to the internal surface of the enclosure, wherein the airflow channel directs air warmed by thermal energy from the at least one electronic device mounted to the internal surface to follow the circular path.

11. The system of claim 1, wherein the at least one baffle further comprises:
a first intake baffle adjacent to a first side of the card cage; and
a first exhaust baffle adjacent to a second side of the card cage;
wherein the first intake and exhaust baffles are oriented to direct at least one airflow pattern within the airflow channel.

12. An apparatus for cooling electronics, the apparatus comprising:
means for creating at least one airflow pattern in a sealed enclosure that includes at least a portion of electronics housed in a card cage;
means, responsive to the means for creating, for directing the at least one airflow pattern in a first direction through the card cage; and
means, responsive to the means for creating and the means for directing, for dissipating thermal energy from the electronics and through at least one conductive surface of the sealed enclosure to maintain the temperature level inside the sealed enclosure below a prescribed temperature threshold level.

13. The apparatus of claim 12, wherein the means for creating include at least one air channel substantially surrounding the electronics within the sealed enclosure.

14. The apparatus of claim 12, wherein the means for directing include a fan assembly that forces the airflow in the at least one direction.

15. The apparatus of claim 12, wherein the means for directing include at least one set of baffles within the sealed enclosure configured to orient the at least one airflow pattern in the first direction.

16. The apparatus of claim 12, wherein the means for dissipating include at least one enclosure panel with opposing inner and outer heat sink fins.

17. The apparatus of claim 12, wherein the means for dissipating include at least one enclosure panel with opposing inner and outer heat sinks fins, the inner and outer heat sinks fins scaled to a first inner length and a first outer length based on a power output of the electronics.

18. An electronics enclosure, the enclosure comprising:
an electronics chassis;
an internal card cage having a backplane and one or more electronic device cards in communication with the backplane, the internal card cage structurally supporting the plurality of electronic device cards within the electronics chassis;
a plurality of extrusion panels configured to attach to the electronics chassis and seal the electronics chassis from an external environment; and
at least one airflow channel formed by the internal card cage and the plurality of attached extrusion panels, the at least one airflow channel configured to direct air warmed by the plurality of electronic device cards to follow a circular path that circulates an airflow across the one or more electronic device cards and the plurality of extrusion panels to dissipate thermal energy generated by the electronic device cards to the external environment.

19. The enclosure of claim 18, wherein the electronics chassis is a remote communications device.

20. The enclosure of claim 18, further comprising an optional fan assembly positioned at a first end within the sealed chassis, the optional fan assembly in communication with the backplane.

21. The enclosure of claim 20, wherein the optional fan assembly comprises at least one variable-speed fan that operates at one or more fan speeds based on the temperature level within the sealed chassis.

22. The enclosure of claim 18, wherein the plurality of extrusion panels comprises at least one set of heat sinks with opposing inner and outer finned surfaces.

23. The enclosure of claim 18, wherein the one or more electronic device cards comprise at least one of:
a system controller;
an input/output module in communication with the system controller, the input/output module operable to send and receive communication data between at least one external device and the system controller; and
a plurality of transceiver modules in communication with the input/output module and the system controller.

24. The enclosure of claim 18, further comprising at least one linear power amplifier mounted on at least one of the extrusion panels.

25. The enclosure of claim 23, wherein the system controller ensures that the prescribed temperature threshold does not exceed an electronic component temperature operating range.

26. A method for managing thermal energy in a sealed enclosure, the method comprising:
circulating air through a closed circular path within a sealed enclosure;
directing air to flow across at least one electronic device card within the sealed enclosure; and
removing thermal energy from the air by directing the air to flow across one or more internal surface of the sealed enclosure.

27. The method of claim 26, wherein circulating air through a closed circular path comprises convectively circulating the air through the closed circular path.

28. The method of claim 26, wherein circulating air through a closed circular path comprises forced air circulation through the closed circular path.

29. The method of claim 26, wherein directing the air to flow across at least one electronic device card further comprises directing the air through and airflow channel comprises of at least one of a baffle and a heat sink fin.

30. The method of claim 26, wherein removing thermal energy from the air comprises directing the air to flow across thermally-conductive inner heat sink fins to dissipate the thermal energy to an external environment of the sealed enclosure through outer heat sink fins.

31. A method for producing a thermal management system for a sealed enclosure, the method comprising:
forming a chassis for housing electronics, wherein the chassis is configured to be sealable from an external environment through one or more thermally conductive panels that mount to the chassis; and
locating a card cage within the chassis between an intake baffle and an exhaust baffle, wherein with the intake baffle and the exhaust baffle are configured to form a circular airflow channel through the card cage when the chassis is sealed using the one or more thermally conductive panels.

32. The method of claim 31, further comprising installing an optional fan assembly to force the directed air through the card cage and across the one or more thermally conductive panels.

33. The method of claim 31, further comprising forming the one or more thermally conductive panels with at least one set of heat sinks, the at least one set of heat sinks further formed with opposing inner and outer fins.
